(19) United States
(12) Patent Application Publication
(10) Pub. No.: US 2013/0309416 A1
(43) Pub. Date: Nov. 21, 2013

(54) ATMOSPHERIC PRESSURE PLASMA TREATMENT APPARATUS AND ATMOSPHERIC PRESSURE PLASMA TREATMENT METHOD

(71) Applicants: Yoshinori Yokoyama, Tokyo (JP); Shinichi Izuo, Tokyo (JP); Yukihisa Yoshida, Tokyo (JP); Takaaki Murakami, Tokyo (JP)

(72) Inventors: Yoshinori Yokoyama, Tokyo (JP); Shinichi Izuo, Tokyo (JP); Yukihisa Yoshida, Tokyo (JP); Takaaki Murakami, Tokyo (JP)

(73) Assignee: Mitsubishi Electric Corporation, Chiyoda-ku Tokyo (JP)

(21) Appl. No.: 13/981,424

(22) PCT Filed: Nov. 21, 2011
(86) PCT No.: PCT/JP2011/076775

§ 371 Date: Jul. 24, 2013

(30) Foreign Application Priority Data
Jan. 25, 2011 (JP) 2011 013347

(51) Int. Cl. C23C 16/50

(52) U.S. Cl. CPC C23C 16/50
USPC 427/569; 118/723 E

(57) ABSTRACT

An atmospheric pressure plasma treatment apparatus includes a moving unit configured to relatively move an atmospheric pressure plasma treatment head and member to be treated, gas supply units configured to supply a reaction gas and a curtain gas, and a control unit. When the atmospheric pressure plasma treatment head and the member are relatively moved, the control unit performs control to increase a flow rate of the reaction gas and the curtain gas from an opposite direction side of a relative moving direction of the member with respect to the atmospheric pressure plasma treatment head and reduce a flow rate of the reaction gas and the curtain gas in the relative moving direction side of the member compared with the flow rates of the reaction gas and the curtain gas flowing when the atmospheric pressure plasma treatment head and the member are not relatively moved.

### FIELD

The present invention relates to an atmospheric pressure plasma treatment apparatus and an atmospheric pressure plasma treatment method for performing plasma treatment under the atmospheric pressure.

### BACKGROUND

There has been an atmospheric pressure plasma treatment apparatus that forms a film on a substrate surface. The atmospheric pressure plasma treatment apparatus supplies a reaction gas to, for example, between opposed electrodes and applies a voltage to the electrodes to cause plasma excitation and generate a plasma gas. The plasma gas generated by the plasma excitation is brought into contact with the surface of a substrate. Exhaust is performed in an outer peripheral section of a contact section of the plasma gas and the substrate.

As such an atmospheric pressure plasma treatment apparatus, for example, Patent Literature 1 discloses a technology for supplying an inert gas to the periphery of a plasma discharge area as a curtain gas with a supply amount larger than a supply amount of a reaction gas, covering the ambient atmosphere with a purge gas, and sucking, from an exhaust duct, the curtain gas and the purge gas blown out toward a substrate and discharging the curtain gas and the purge gas.

### CITATION LIST

### Patent Literature

Patent Literature 1: Japanese Patent Application Laid-Open No. 2006-5007

### SUMMARY

### Technical Problem

However, when a plasma treatment head and the substrate need to be relatively moved, the velocities and the directions of the gases between the plasma treatment head and the substrate are different from the velocities and the directions of the gases in the plasma treatment performed in a state in which the plasma treatment head and the substrate are kept stationary. Therefore, there is a problem in that it is difficult to homogenize electric discharges. If the gas supply amount is increased to reduce the influence of the relative movement, there is a problem in that an increase in manufacturing costs involved in an increase in a consumption of the gases is caused.

The present invention has been devised in view of the above and it is an object of the present invention to obtain an atmospheric pressure plasma treatment apparatus that can attain, while suppressing an increase in the consumption of the gases, homogenization of electric discharges when the plasma treatment head and the substrate are relatively moved.

### Solution to Problem

In order to solve the above problem and in order to attain the above object, an atmospheric pressure plasma treatment apparatus of the present invention, includes: an atmospheric pressure plasma treatment head including a first electrode to which an alternating-current power is applied, a grounded second electrode, a reaction gas channel formed in an outer periphery of the first electrode, a reaction gas supplied to a surface to be treated of a member to be treated passing through the reaction gas channel, an exhaust channel formed in an outer periphery of the reaction gas channel, and a curtain-gas supply channel formed in an outer periphery of the exhaust channel; a moving unit configured to hold the member to be treated to be opposed to the atmospheric pressure plasma treatment head such that the surface to be treated is exposed to the reaction gas supplied from the reaction gas channel and relatively move the atmospheric pressure plasma treatment head and the member to be treated; a gas supply unit configured to cause the reaction gas to pass through the reaction gas channel and cause the curtain gas to pass through the curtain-gas supply channel; an exhaust unit configured to exhaust the gasses present between the atmospheric pressure plasma treatment head and the surface to be treated from the exhaust channel; and a control unit configured to control the gas supply unit and the exhaust unit. The control unit controls, in an atmosphere in a state in which an electric field is generated between the first electrode and the second electrode by the application of the alternating-current power, a flow rate of the gases exhausted from the exhaust channel to be larger than a flow rate of the reaction gas supplied from the reaction gas channel and controls a flow rate of the curtain gas supplied from the curtain-gas supply channel to be larger than a flow rate of the gases exhausted from the exhaust channel and, when the atmospheric pressure plasma treatment head and the member to be processed are relatively moved by the moving unit, while substantially fixing a total flow rate of the reaction gas from the reaction gas channel and a total flow rate of the curtain gas from the curtain-gas supply channel, increases a flow rate of the reaction gas and a flow rate of the curtain gas from an opposite direction side of a relative moving direction of the member to be treated with respect to the atmospheric pressure plasma treatment head and reduces a flow rate of the reaction gas and a flow rate of the curtain gas in the relative moving direction side of the member to be processed compared with the flow rates of the reaction gas and the curtain gas flowing when the atmospheric pressure plasma treatment head and the member to be treated are not relatively moved, and controls an exhaust flow rate such that a gas stream between the member to be treated and the atmospheric pressure plasma treatment head flows to an outside of the atmospheric pressure plasma treatment head in an outer peripheral section of the curtain-gas supply channel and flows to the exhaust channel in a collecting section of the exhaust channel.

### ADVANTAGEOUS EFFECTS OF INVENTION

According to the present invention, because the flow rates of the gases and the exhaust are controlled, in plasma treatment in the atmosphere, there is an effect that it is possible to attain, while suppressing an increase in the consumption of the gasses, homogenization of electric discharges when the plasma treatment head and the substrate are relatively moved.

### BRIEF DESCRIPTION OF DRAWINGS

FIG. 1 is a sectional view of a schematic configuration of an atmospheric pressure plasma treatment apparatus according to a first embodiment of the present invention.

FIG. 2 is a top view of an atmospheric pressure plasma treatment head.

FIG. 3 is a sectional view of the atmospheric pressure plasma treatment apparatus in a state of flows of gases flowing between a substrate and the atmospheric pressure plasma treatment head when a stage and the atmospheric pressure plasma treatment head remain stationary with respect to each other.

FIG. 4 is a sectional view of the atmospheric pressure plasma treatment apparatus in a state of flows of the gases flowing between the substrate and the atmospheric pressure plasma treatment head when the stage and the atmospheric pressure plasma treatment head are relatively moving.

FIG. 5 is a graph of a relation between a moving velocity of the stage and the velocity of a first gas stream.

FIG. 6 is a sectional view of a schematic configuration of an atmospheric pressure plasma treatment apparatus according to a second embodiment of the present invention.

FIG. 7 is a sectional view of a schematic configuration of an atmospheric pressure plasma treatment apparatus according to a third embodiment of the present invention.

FIG. 8 is a sectional view of a schematic configuration of an atmospheric pressure plasma treatment apparatus according to a fourth embodiment of the present invention.

FIG. 9 is a sectional view of a schematic configuration of an atmospheric pressure plasma treatment apparatus according to a fifth embodiment of the present invention.

FIG. 10 is a sectional view of a schematic configuration of an atmospheric pressure plasma treatment apparatus according to a sixth embodiment of the present invention.

FIG. 11-1 is a sectional view of a schematic configuration of an atmospheric pressure plasma treatment apparatus according to a seventh embodiment of the present invention and is a diagram of a state in which a stage is moving in a direction indicated by an arrow X.

FIG. 11-2 is a sectional view of the schematic configuration of the atmospheric pressure plasma treatment apparatus according to the seventh embodiment of the present invention and is a diagram of a state in which the stage is moving in a direction indicated by an arrow Y.

FIG. 12-1 is a sectional view of a schematic configuration of an atmospheric pressure plasma treatment apparatus according to a first modification of the seventh embodiment and is a diagram of a state in which the stage is moving in the direction indicated by the arrow X.

FIG. 12-2 is a sectional view of the schematic configuration of the atmospheric pressure plasma treatment apparatus according to the first modification of the seventh embodiment and is a diagram of a state in which the stage is moving in the direction indicated by the arrow Y.

FIG. 13 is a flowchart for explaining a schematic procedure of an atmospheric pressure plasma treatment method by an atmospheric pressure plasma treatment apparatus.

### DESCRIPTION OF EMBODIMENTS

Atmospheric pressure plasma treatment apparatuses and atmospheric pressure plasma treatment methods according to embodiments of the present invention are explained in detail below based on the drawings. The present invention is not limited by the embodiments.

### First Embodiment

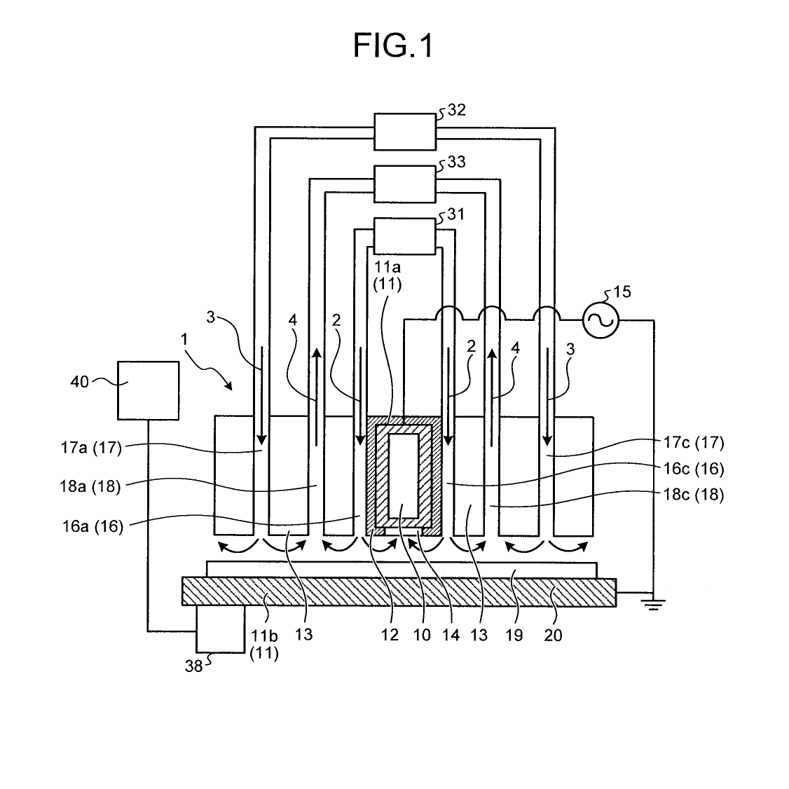

FIG. 1 is a sectional view of a schematic configuration of an atmospheric pressure plasma treatment apparatus according to a first embodiment of the present invention. As shown in FIG. 1, an atmospheric pressure plasma treatment head 1 has a function of supplying a reaction gas to a plasma generation region along arrows 2 and a function of supplying a curtain gas including an inert gas to the periphery of the plasma generation region along arrows 3.

Further, the atmospheric pressure plasma treatment head 1 has a function of exhausting the reaction gas in an unreacted state, gas decomposed by plasma, a reaction generated gas generated by reaction with a substrate, and the curtain gas (these gases are hereinafter generally referred to as unreacted gas and the like) along arrows 4.

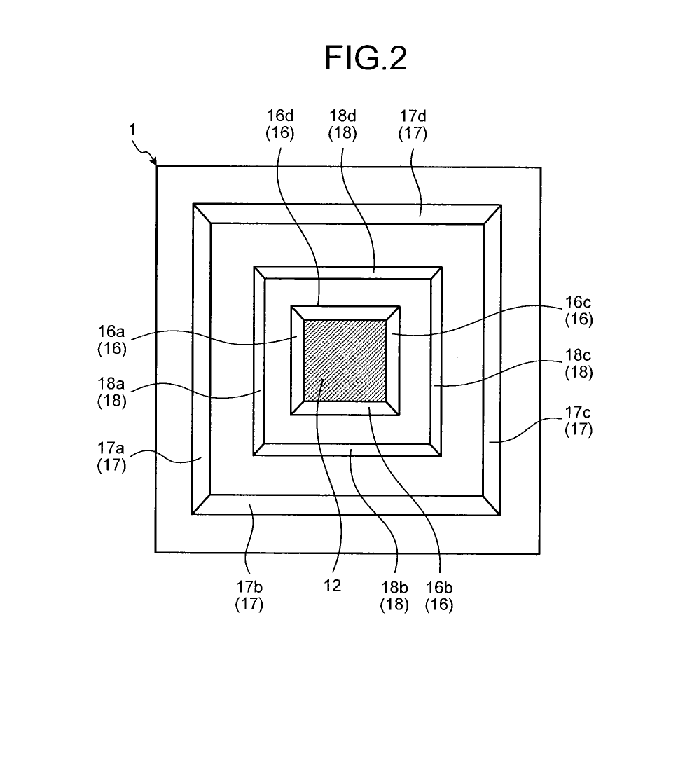

FIG. 2 is a top view of the atmospheric pressure plasma treatment head. The atmospheric pressure plasma treatment apparatus according to the first embodiment includes, as shown in FIGS. 1 and 2, a high-frequency electrode 11 (an input-side high-frequency electrode 11a (a first electrode) mounted with a cooling mechanism 10 that is in contact with a solid source 14 having a flat shape and can apply high-frequency power to the solid source 14, an insulator 12 configured to prevent arc generation, channel forming members 13 arranged in the outer peripheral section of the insulator 12, the solid source 14 to which the high-frequency power is input, a power supply 15 configured to apply the high-frequency power to the high-frequency electrode 11, and a grounded stage 20 configured to hold a substrate (a member to be treated) 19 such that a surface to be treated of the substrate 19 is substantially parallel to a reaction gas channel. The stage 20 functions as a ground-side high-frequency electrode 11b (a second electrode) as well. In the following explanation, the solid source 14 is referred to as target as well when physical film formation is performed and is referred to as electrode as well when simple surface treatment is performed. The solid source 14 is referred to as solid source 14 when chemical film formation is performed.

A reaction gas channel 16 for supplying the reaction gas along the arrows 2, a curtain-gas supply channel 17 for supplying the curtain gas including the inert gas along the arrows 3, and an exhaust channel 18 for exhausting the unreacted gas and the like along the arrows 4 are formed by the channel forming members 13. The reaction gas channel 16, the curtain-gas supply channel 17, and the exhaust channel 18 are formed to surround the periphery of the input-side high-frequency electrode 11a.

The channels 16, 17, and 18 are divided into four sections as shown in FIG. 2 (reaction gas channels 16a to 16d, curtain-gas supply channels 17a to 17d, and exhaust channels 18a to 18d). The exhaust channel 18 is formed in the outer periphery of the reaction gas channel 16 and the curtain-gas supply channel 17 is formed in the outer periphery of the exhaust channel 18. That is, the channels 16, 17, and 18 are formed to be arranged in the order of the reaction gas channel 16, the exhaust channel 18, and the curtain-gas supply channel 17 from the input-side high-frequency electrode 11a toward the outer side.

As the material of the high-frequency electrode 11, for example, copper, aluminum, stainless steel, and brass can be used. The high-frequency electrode 11 includes the cooling mechanism 10 configured to lead in cooling water to cool the high-frequency electrode 11. The insulator 12 is provided in the periphery of the high-frequency electrode 11 including the substrate 19 side except the solid source 14 to prevent arc generation. The frequency of the high-frequency electrode 11 is not limited to 13.56 MHz often used for a high-frequency electrode. The frequency can be any frequency in a range of a low frequency of several kilohertz to a high frequency of several hundred megahertz as long as stable plasma discharge is possible at the frequency.

As the insulator 12, for example, polyethylene terephthalate, aluminum oxide, titanium oxide, and quartz can be used. The reaction gas is supplied to between the substrate 19 and the solid source 14 passing through the reaction gas channel 16 in the direction indicated by the arrows 2. A gap region present between the high-frequency electrodes 11, i.e., the input-side high-frequency electrode 11a and the ground-side high-frequency electrode 11b is a plasma generation region.

The input-side high-frequency electrode 11a is provided in a position further apart from the stage 20 than the other sections of the atmospheric pressure plasma treatment head 1. Consequently, the reaction gas easily flows into the plasma generation region. It is possible to reduce an amount of the reaction gas flowing to the exhaust channel 18.

A protrusion can be provided in a section between the reaction gas channel 16 and the exhaust channel 18. In this case, as in the case explained above, because the reaction gas less easily flows to the exhaust channel 18 side, the reaction gas easily flows into the plasma generation region. Therefore, it is possible to reduce an amount of the reaction gas flowing to the exhaust channel 18.

The channel forming members 13 are desirably formed of a material that does not react with the unreacted gas and the like in use and are preferably formed of aluminum, stainless steel, aluminum oxide, or the like. The reaction gas channel 16 is formed to surround the input-side high-frequency electrode 11a from the outer side. A reaction-gas supply unit (a gas supply unit) 31 is connected to the reaction gas channel 16. The reaction gas is supplied from the reaction-gas supply unit 31.

The exhaust channel 18 is provided to surround the plasma generation region from the outer side. An exhaust fan (an exhaust unit) 33 is connected to the exhaust channel 18. It is possible to discharge the unreacted gas and the like to an exhaust gas treating section (not shown in the figure) through the exhaust channel 18 by causing the exhaust fan 33 to operate.

The curtain-gas supply channel 17 for supplying the curtain gas along the arrows 3 is provided further on the outer side than the exhaust channel 18. The substrate 19 side of the curtain-gas supply channel 17 is a spouting port for the curtain gas. A curtain-gas supply unit (a gas supply unit) 32 is connected to the curtain-gas supply channel 17. The curtain gas is supplied from the curtain-gas supply unit 32. The inert gas spouted from the curtain-gas supply channel 17 is sprayed against the substrate 19. A part of the inert gas is sucked from the exhaust channel 18 and the remainder is emitted to the outside atmosphere.

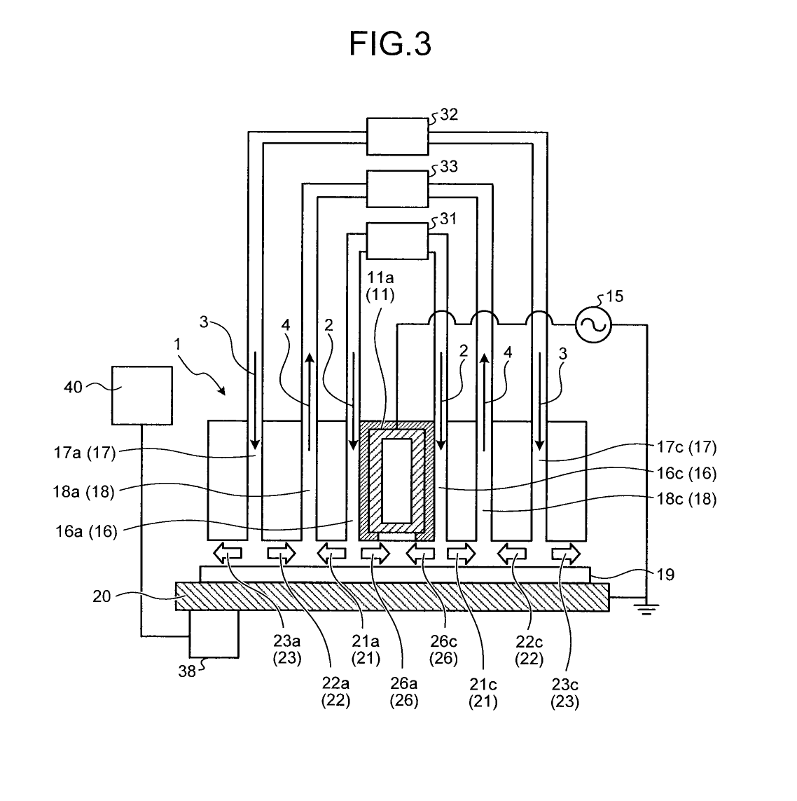

FIG. 3 is a sectional view of the atmospheric pressure plasma treatment apparatus in a state of flows of the gases flowing between the substrate 19 and the atmospheric pressure plasma treatment head 1 when the stage 20 and the atmospheric pressure plasma treatment head 1 remain stationary with respect to each other. When the stage 20 and the atmospheric pressure plasma treatment head 1 remain stationary, as shown in FIG. 3, a necessary relation among a flow rate of the reaction gas, a flow rate of the curtain gas, and a flow rate of exhaust needs to satisfy a relation of the reaction gas<the exhaust<the curtain gas.

When such a relation is satisfied, the plasma generation region has a positive pressure. All of the reaction gas and the unreacted gas and the like are blocked by the flow of the curtain gas and exhausted from the exhaust channel 18. Further, the curtain gas is emitted to the outside atmosphere as well. The outside atmosphere does not flow into the plasma generation region.

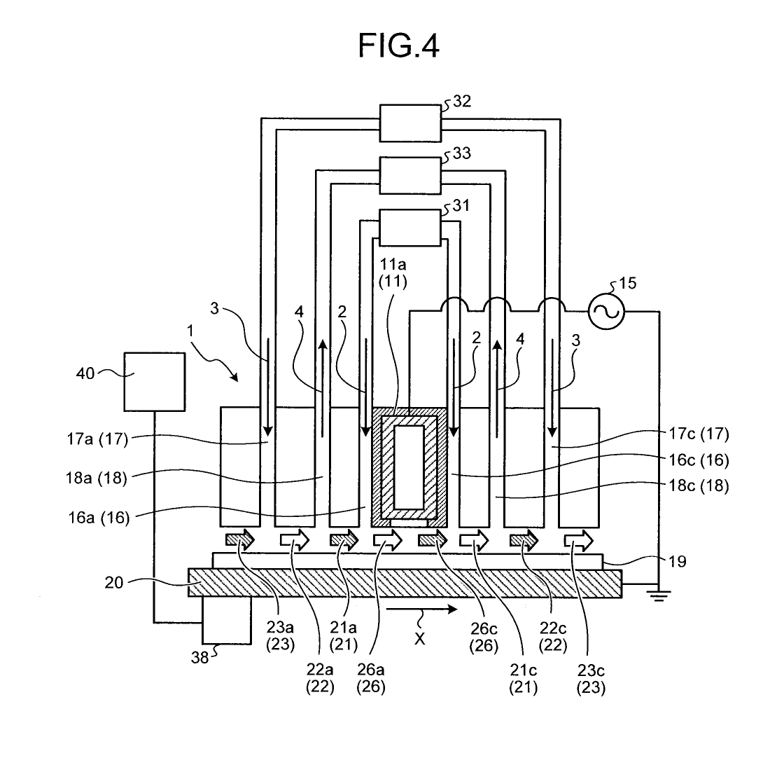

FIG. 4 is a sectional view of the atmospheric pressure plasma treatment apparatus in a state of flows of the gases flowing between the substrate 19 and the atmospheric pressure plasma treatment head 1 when the stage 20 and the atmospheric pressure plasma treatment head 1 are relatively moving. The stage 20 is moved by a moving unit 38. The moving unit 38 is, for example, a motor. The atmospheric pressure plasma treatment head 1 can be configured to move.

When the stage 20 and the atmospheric pressure plasma treatment head 1 relatively move to treat the entire surface of the substrate 19, for example, when the atmospheric pressure plasma treatment head 1 stands still and the stage 20 moves in a direction indicated by an arrow X, a place is formed where the direction of a total flow velocity is reversed from a direction in a stationary state.

If supply amounts of the reaction gas and the curtain gas are increased as a whole and an exhaust flow rate is also increased to overcome the moving velocity of the stage 20, it is possible to eliminate the reversal of the direction of the total flow velocity. However, in a method of increasing an amount of the gases according to an increase in the moving velocity, costs increase because the consumption of the reaction gas and the curtain gas also increases.

Therefore, to suppress the supply amount of the reaction gas and the supply amount of the curtain gas, the supply amount of the reaction gas and the supply amount of the curtain gas are increased on an upstream side (an opposite direction side of a relative moving direction of the stage 20 with respect to the atmospheric pressure plasma treatment head 1), the supply amount of the reaction gas and the supply amount of the curtain gas are reduced on a downstream side (the relative moving direction side of the stage 20 with respect to the atmospheric pressure plasma treatment head 1), and an exhaust amount is appropriately distributed according to the supply amounts of the reaction gas and the curtain gas.

The adjustment of the supply amount of the reaction gas and the supply amount of the curtain gas is performed by a control unit 40. For example, the control unit 40 receives feedback of the moving velocity of the stage 20 from the moving unit 38, adjusts opening degrees of valves provided in the reaction-gas supply unit 31 and the curtain-gas supply unit 32, and adjusts the supply amounts of the gases.

If the curtain gas amount and the exhaust amount are controlled according to the direction of the relative movement of the stage 20 and the atmospheric pressure plasma treatment head 1 to cause the flows of the gases shown in FIG. 3, it is possible to suppress the supply amounts of the gases. Therefore, the reaction gas and the like less easily flow out to the outside atmosphere. The outside atmosphere less easily flows into the plasma generation region. Therefore, it is possible to configure the atmospheric pressure plasma treatment apparatus that can perform homogeneous discharges.

A treatment example in the atmospheric pressure plasma treatment apparatus having such a configuration is explained with reference to film formation of a silicon film as an example. First, the power supply 15 is connected to the high-frequency electrode 11 to prepare for an input of electric power to the input-side high-frequency electrode 11a side where the solid source 14 is present. The stage 20 functioning as the ground-side high-frequency electrode 11b as well is grounded. High-frequency power is input after gas and exhaust flow rates explained below are stabilized.

The substrate 19 is arranged on the stage 20 with the surface to be treated facing up such that plasma can be irradiated on a surface on which a film of silicon is formed. The solid source 14 is formed of a silicon plate having purity equal to or higher than 99.99999%.

Subsequently, the reaction gas is fed to the reaction gas channel 16, the curtain gas is fed to the curtain-gas supply channel 17, and exhaust is performed through the exhaust channel 18. 400 sccm of a hydrogen gas is fed to the reaction gas channel 16 as the reaction gas. More specifically, 100 sccm of the hydrogen gas is fed to each of the reaction gas channels 16a, 16b, 16c, and 16d divided into the four sections.

5000 sccm of an inert gas (helium) is fed to the curtain-gas supply channel 17 as the curtain gas. More specifically, 1250 sccm of the inert gas is fed to each of the curtain-gas supply channels 17a, 17b, 17c, and 17d divided into the four sections.

An exhaust flow rate of the exhaust channel 18 is 1000 sccm. 250 sccm of the gases are exhausted from each of the exhaust channels 18a, 18b, 18c, and 18d divided into four sections. A flow rate relation at this point satisfies a relation of the reaction gas<the exhaust amount<the curtain gas amount. As shown in FIG. 3, first gas streams 21 (21a and 21c), second gas streams 22 (22a and 22c), third gas streams 23 (23a and 23c), and fourth gas streams 26 (26a and 26c) flow in directions indicated by arrows. A condition that the unreacted gas and the like do not flow out to the outside atmosphere and the outside atmosphere does not flow into the plasma generation region is satisfied.

When the substrate 19 and the atmospheric pressure plasma treatment head 1 remain stationary, the flow rates explained above are sufficient. However, when a film is formed on a large substrate or the like, it is necessary to relatively move a head and the substrate. For example, as shown in FIG. 4, when the stage 20 moves at velocity V in the direction indicated by the arrow X, if the gases are supplied at amounts same as the gas amounts in the stationary state, the directions of the flows of the gas streams 21, 22, 23, and 26 are sometimes opposite to the directions shown in FIG. 3.

In the example shown in FIG. 4, the directions of the flows of the first gas stream 21a on the upstream side of the first gas stream 21, the second gas stream 22c on the downstream side of the second gas streams 22, the third gas stream 23a on the upstream side of the third gas streams 23, and the fourth gas stream 26c on the downstream side of the fourth gas streams 26 are opposite to the directions shown in FIG. 3.

That is, when the moving velocity V of the stage 20 is equal to or higher than the velocity of the gas streams 21, 22, 23, and 26, the directions of the flows are opposite directions. The condition that the unreacted gas and the like do not flow out to the outside atmosphere and the outside atmosphere does not flow into the plasma generation region is not satisfied.

To prevent this situation, it is necessary to increase the reaction gas, curtain gas, and exhaust amounts to have velocities that overcome the moving velocity V of the stage 20. However, the increase in the curtain gas and reaction gas amounts leads to an increase in costs. Therefore, in the first embodiment, the reaction gas supply amount, the curtain gas supply amount, and the exhaust amount are adjusted on the upstream side and the downstream side during the stage movement.

For example, when the stage 20 is moving in the direction indicated by the arrow X in FIG. 4, 250 sccm of the hydrogen gas is supplied to the reaction as channel 16a on the upstream side, 50 sccm of the hydrogen gas is supplied to the reaction gas channel 16c on the downstream side, and 50 sccm of the hydrogen gas is supplied to each of the reaction gas channels 16b and 16d (see FIG. 2 as well) on the side surfaces. Further, 2000 sccm of the helium is supplied to the curtain-gas supply channel 17a on the upstream side, 500 sccm of the helium is supplied to the curtain-gas supply channel 17c on the downstream side, and 500 sccm of the helium is supplied to each of the curtain-gas supply channels 17b and 17d on the side surfaces. 1500 sccm of exhaust is performed from the exhaust channel 18a on the upstream side, 500 sccm of exhaust is performed from the exhaust channel 18c on the downstream side, and 500 sccm of exhaust is performed from each of the exhaust channels 18b and 18d on the side surfaces.

When the gas amounts are adjusted in this way, the directions of the gas streams 21a, 22c, and 23a are the same as the directions in the stationary state shown in FIG. 3. The condition that the unreacted gas and the like do not flow out to the outside atmosphere and the outside atmosphere does not flow into the plasma generation region is satisfied. Further, discharges are stabilized because the flow of the reaction gas is stabilized. That is, the directions of the flows of the gas streams between the substrate 19 and the atmospheric pressure plasma treatment head 1 are important.

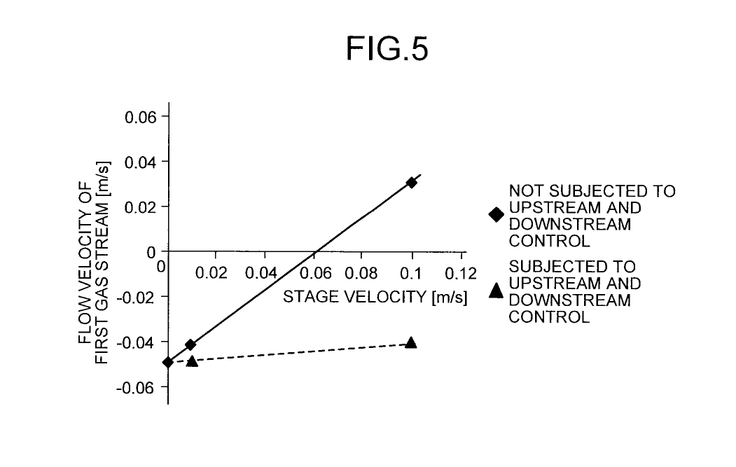

A relation between the moving velocity V of the stage 20 and the velocity of the first gas stream 21a is shown in FIG. 5. In FIG. 4, the direction indicated by the arrow X is a positive direction and a direction opposite to the direction is a negative position. A flow velocity is a value in the center of a space between the substrate 19 and the atmospheric pressure plasma treatment head 1.

At a flow velocity 0.06 m/s in the reaction gas channel 16a and a flow velocity 0.08 m/s in the curtain-gas supply channel 17a in the stationary state (the moving velocity of the stage 20 is 0 m/s) and a flow velocity of 0.02 m/s in the exhaust channel 18a, a flow velocity of the first gas stream 21a is −0.05 m/s. The first gas stream 21a flows in the direction shown in FIG. 3.

When the moving velocity of the stage 20 is increased to 0.01 m/s, as shown in FIG. 5, the velocity of the first gas stream 21a only slightly decreases. The condition that the unreacted gas and the like do not flow out to the outside atmosphere and the outside atmosphere does not flow into the plasma generation region is satisfied.

When the moving velocity of the stage 20 is increased to 0.1 m/s, as shown in FIG. 5, the velocity of the first gas stream 21a changes to 0.03 m/s. Therefore, as shown in FIG. 4, the direction of the flow velocity is reversed. The condition that the unreacted gas and the like do not flow out to the outside atmosphere and the outside atmosphere does not flow into the plasma generation region is satisfied.

At this point, when a flow velocity in the exhaust channel 18c on the downstream side is increased to 0.05 m/s, a flow velocity in the curtain-gas supply channel 17c on the downstream side is reduced to 0.04 m/s, a flow velocity in the reaction gas channel 16c on the downstream side is reduced to 0.04 m/s, a flow velocity in the exhaust channel 18a on the upstream side is increased to 0.1 m/s, a flow velocity in the curtain-gas supply channel 17a on the upstream side is increased to 0.1 m/s, and a flow velocity in the reaction gas channel 16a on the upstream side is increased to 0.08 m/s, the flow velocity of the first gas stream 21a subjected to the upstream and downstream control shown in FIG. 5 changes to −0.04 m/s. The direction of the flow velocity is maintained in the same direction at the stationary time. That is, the condition that the unreacted gas and the like do not flow out to the outside atmosphere and the outside atmosphere does not flow into the plasma generation region is satisfied.

That is, if the velocity of the first gas stream 21a is sufficiently higher than the moving velocity of the stage 20, the condition is satisfied even if the flow rate control is not performed but, if the moving velocity of the stage 20 exceeds the velocity of the first gas stream 21a, the condition is not satisfied. The first gas stream 21a is explained as the example above. However, the same applies in other gas streams.

Therefore, when the stage 20 is moved at high velocity, it is possible to control the directions of the gas streams 21, 22, and 23 to directions for satisfying the condition by taking measures for increasing the flow velocities of the gas streams 21a, 22c, and 23a.

For example, even when the stage 20 is moved at high velocity, it is possible to perform stable film formation by taking measures such as reducing the distance between the substrate 19 and the atmospheric pressure plasma treatment head 1 or providing chokes in outlets of the channels to increase the flow velocities.

An effect of smoothing the supply of the reaction gas to the solid source 14 is attained by setting, to facilitate inflow of the reaction gas into the solid source 14, the height of the solid source 14 in a position further away from the substrate 19 than the channel forming members 13.

In this way, a clean environment in which little oxygen is present in the plasma generation region is created. The solid source 14 (e.g., a silicon solid source) is cooled by the cooling mechanism 10 to maintain low temperature. The substrate 19 is heated by a heater (not shown in the figure) built in the stage 20 to maintain high temperature.

When a high-frequency electric field is applied to the silicon solid source 14 including a volatile hydride from the power supply 15 via the high-frequency electrode 11, the reaction gas, for example, a hydrogen gas stream flowing from the reaction gas channel 16 simultaneously causes the following processes between the solid source 14 and the substrate: etching due to generation and volatilization of the hydride (SiHx) (x=1, 2, . . . ) of silicon of the solid source 14 caused by a chemical reaction with excited atomic hydrogen by hydrogen plasma and deposition of a solid source substance caused by re-decomposition of the hydride, which is generated by the etching, in plasma.

On the surface of the solid source 14 on a low temperature side, the speed of the reaction is higher in the etching and lower in the deposition. On the other hand, on the surface of the substrate 19 on a high temperature side, the speed of the deposition is higher and the speed of the etching is lower. Therefore, a temperature difference between the solid source 14 and the substrate 19 is set moderately large. Consequently, a speed difference between the etching and the deposition increases, relatively quick substance movement from the solid source on the low temperature side to the substrate on the high temperature side occurs. The silicon is deposited on the substrate 19.

Such substance movement not performed under decompression of a closed space is called atmospheric pressure plasma chemical transport method. It is desirable to set the temperature difference between the high temperature side and the low temperature side to about 285° C. by, for example, setting the low temperature to, for example, 15° C. and setting the high temperature to, for example, about 300° C. Therefore, if the low temperature side is set to −35° C., it is preferable to set the high temperature side to about 250° C. However, if the temperature difference is equal to or larger than 100° C., a combination of the temperatures can be changed as appropriate.

It is preferable to set the space between the substrate 19 and the atmospheric pressure plasma treatment head 1 to be equal to or smaller than about 5 mm because the hydride of the silicon has to reach the substrate. It is preferable that the space is equal to or smaller than 1 mm if possible. Because the flow velocity between the substrate 19 and the atmospheric pressure plasma treatment head 1 increases, it goes without saying that it is possible to increase scan speed even if a flow rate is the same.

Consequently, the atmospheric pressure plasma treatment apparatus is realized that does not need to cover the atmosphere with a purge gas and can perform the atmospheric pressure plasma treatment with a simple configuration and at low costs.

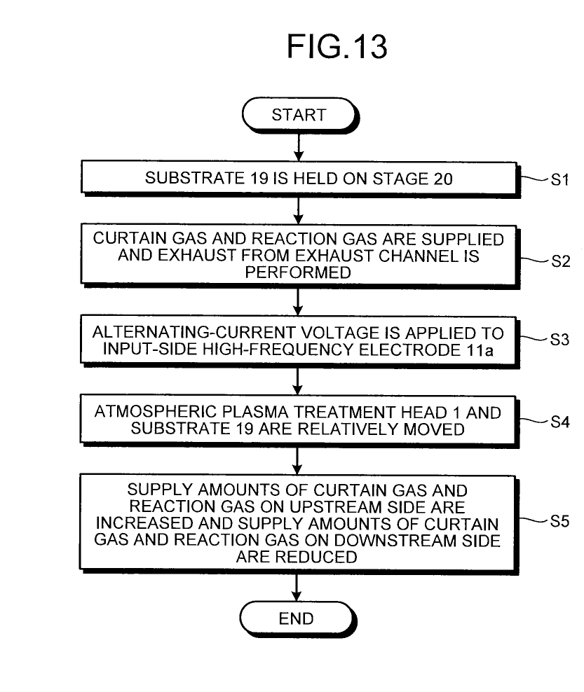

FIG. 13 is a flowchart for explaining a schematic procedure of an atmospheric pressure plasma treatment method by the atmospheric pressure plasma treatment apparatus explained above. First, the substrate 19 is held on the stage 20 (step S1). The curtain gas and the reaction gas are supplied and exhaust from the exhaust channel is performed (step S2). An alternating-current voltage is applied to the input-side high-frequency electrode 11a (step S3). When the stage 20 is moved and the atmospheric pressure plasma treatment head 1 and the substrate 19 are relatively moved (step S4), the supply amounts of the curtain gas and the reaction gas on the upstream side are increased and the supply amounts of the curtain gas and the reaction gas on the downstream side are reduced (step S5). At step S5, the exhaust amount is increased. The increase is controlled to be larger on the upstream side than the downstream side.

The example of the film formation performed using the solid source 14 is explained above. However, it goes without saying that a film can be formed in the same manner as the normal sputtering apparatus by using an argon gas as the reaction gas and using metal such as Si, gold, silver, copper, titanium, or aluminum or ceramic such as alumina or zirconium as the target 14.

The shape of the atmospheric pressure plasma treatment head 1 is shown as a square pole shape. However, the shape is not limited to this. For example, the shape can be a cylindrical shape or other shapes.

### Second Embodiment

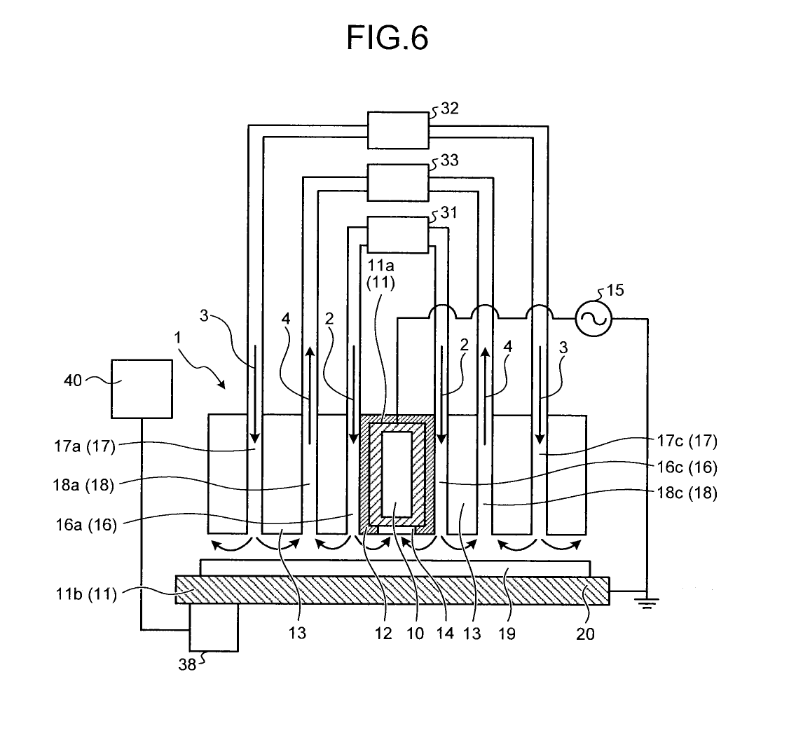

FIG. 6 is a sectional view of a schematic configuration of an atmospheric pressure plasma treatment apparatus according to a second embodiment of the present invention. Components same as the components in the first embodiment are denoted by the same reference numerals and signs and detailed explanation of the components is omitted. The second embodiment is characterized in that the solid source 14 or the target 14 is not used in the atmospheric pressure plasma treatment head 1 and an electrode 14 is exposed to the surface. As the electrode 14, for example, aluminum, stainless steel, or copper can be used. Naturally, other metal can be used as long as the metal functions as an electrode.

For example, a monosilane gas, a hydrogen gas, or a helium gas is fed to the reaction gas channel 16 as a reaction gas, argon is fed to the curtain-gas supply channel 17 as a curtain gas, and exhaust is performed from the exhaust channel 18. Supply amounts of the gases and an exhaust amount are adjusted in the same manner as in the first embodiment to set the directions of gas streams in the directions shown in FIG. 3.

When high-frequency power is applied to the high-frequency electrode 11, plasma is generated between the high-frequency electrodes 11 and a silicon film can be formed on the substrate 19. The high-frequency electrode 11 is cooled by the cooling mechanism 10, whereby heating by the high-frequency power can be prevented and arc transfer caused by thermoelectron generation due to heat generation of the high-frequency electrode can be prevented. The frequency of the high-frequency electrode 11 is not limited to 13.56 MHz often used for a high-frequency electrode. The frequency can be any frequency in a range of a low frequency of several kilohertz to a high frequency of several hundred megahertz as long as stable plasma discharge is possible at the frequency.

Depending on a film material for film formation, it is possible to obtain a satisfactory film by mounting a heating mechanism on the stage 20 on which the substrate 19 is placed. For example, in silicon film formation, it is desirable to set a substrate temperature in a range of 200° C. to 400° C. When the substrate 19 and the atmospheric pressure plasma treatment head 1 are relatively moved to form a film in a large area, as explained in the first embodiment, it is possible to safely and inexpensively form the film by adjusting the curtain gas amount and the exhaust amount upstream and downstream to set the directions of the gas streams same as the directions shown in FIG. 3.

### Third Embodiment

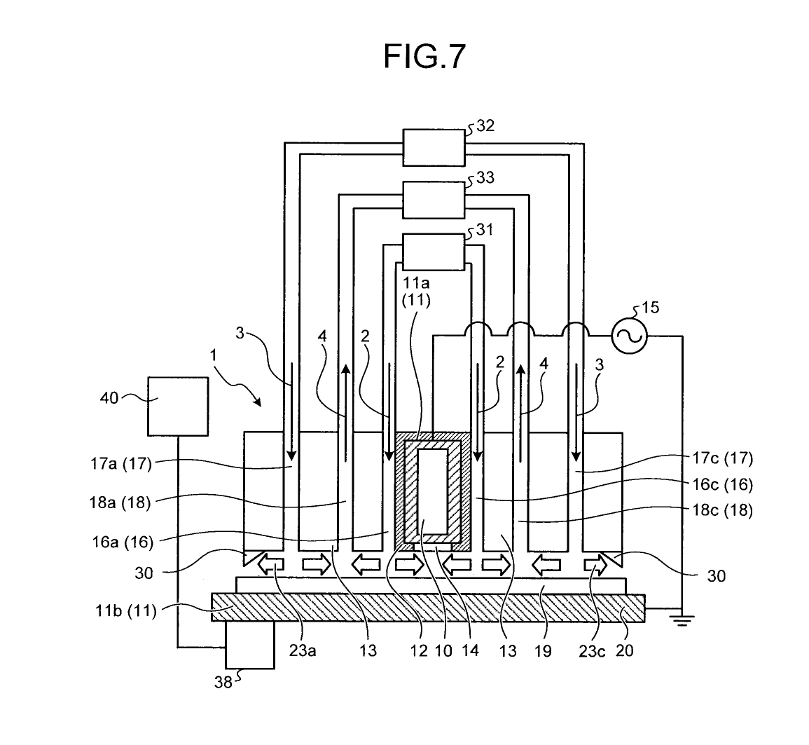

FIG. 7 is a sectional view of a schematic configuration of an atmospheric pressure plasma treatment apparatus according to a third embodiment of the present invention. Components same as the components in the embodiments explained above are denoted by the same reference numerals and signs and detailed explanation of the components is omitted. The third embodiment is characterized in that a protrusion 30 is provided in the outer peripheral section of the atmospheric pressure plasma treatment head 1. Consequently, there is an effect of increasing the velocities of the gas streams 23a and 23c flowing out from the curtain-gas supply channel 17 to the outside atmosphere and suppressing inflow of the outside atmosphere with smaller gas amounts. Therefore, it is possible to safely and inexpensively form a film.

### Fourth Embodiment

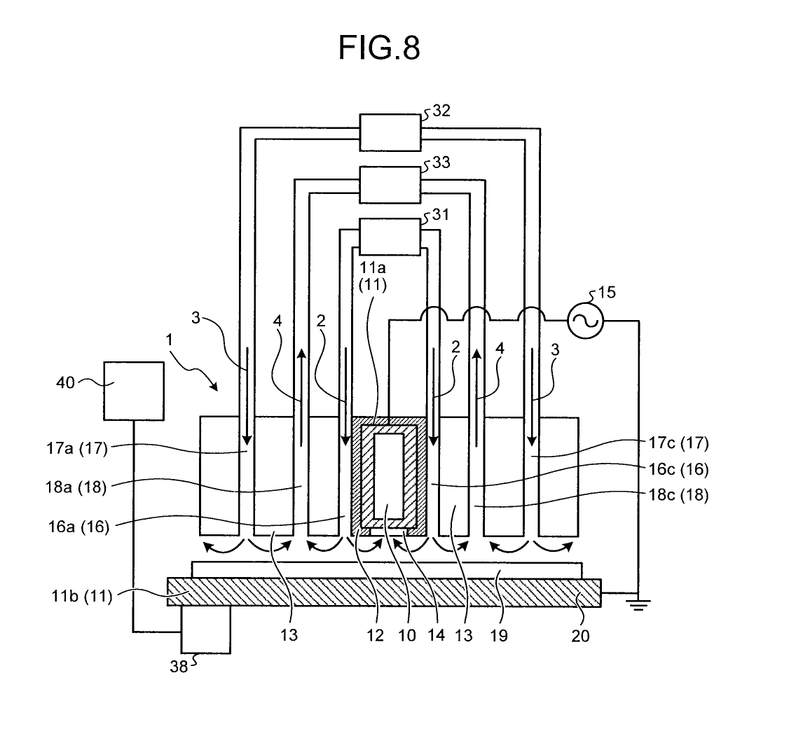

FIG. 8 is a sectional view of a schematic configuration of an atmospheric pressure plasma treatment apparatus according to a fourth embodiment of the present invention. Components same as the components in the embodiments explained above are denoted by the same reference numerals and signs and detailed explanation of the components is omitted. The fourth embodiment is characterized in that hydrogen or the like is fed to the reaction gas channel 16 to generate hydrogen plasma and perform surface treatment for the substrate 19.

For example, a hydrogen gas is fed to the reaction gas channel 16 as a reaction gas, nitrogen is fed to the curtain-gas supply channel 17 as a curtain gas, and exhaust is performed from the exhaust channel 18. Supply amounts of the gases and an exhaust amount are adjusted in the same manner as in the first embodiment to set the directions of gas streams in the directions shown in FIG. 3.

When high-frequency power is applied to the high-frequency electrode 11, hydrogen plasma is generated between the high-frequency electrodes 11 and between the high-frequency electrode 11 and the substrate 19 and the hydrogen plasma can be irradiated on the substrate 19. The high-frequency electrode 11 is cooled by the cooling mechanism 10, whereby heating by the high-frequency power can be prevented and arc transfer caused by thermoelectron generation due to heat generation of the high-frequency electrode can be prevented. The frequency of the high-frequency electrode 11 is not limited to 13.56 MHz often used for a high-frequency electrode. The frequency can be any frequency in a range of a low frequency of several kilohertz to a high frequency of several hundred megahertz as long as stable plasma discharge is possible at the frequency.

When argon or the like is supplied as the reaction gas, it is possible to irradiate plasma of the argon. Depending on a type of plasma to be irradiated, when the substrate 19 is moved to form a film in a large area, as explained in the first embodiment, it is possible to safely and inexpensively perform homogenous surface treatment by adjusting the reaction gas amount, the curtain gas amount, and the exhaust amount upstream and downstream to set the directions of the gas streams same as the directions shown in FIG. 3.

In the example explained above, the hydrogen gas is used. However, it goes without saying that it is possible to, while keeping a clean environment in the periphery, subject the substrate to discharge treatment and use the substrate for surface reforming by discharging an argon gas, an oxygen gas, a nitrogen gas, or the like alone or in combination as the reaction gas.

### Fifth Embodiment

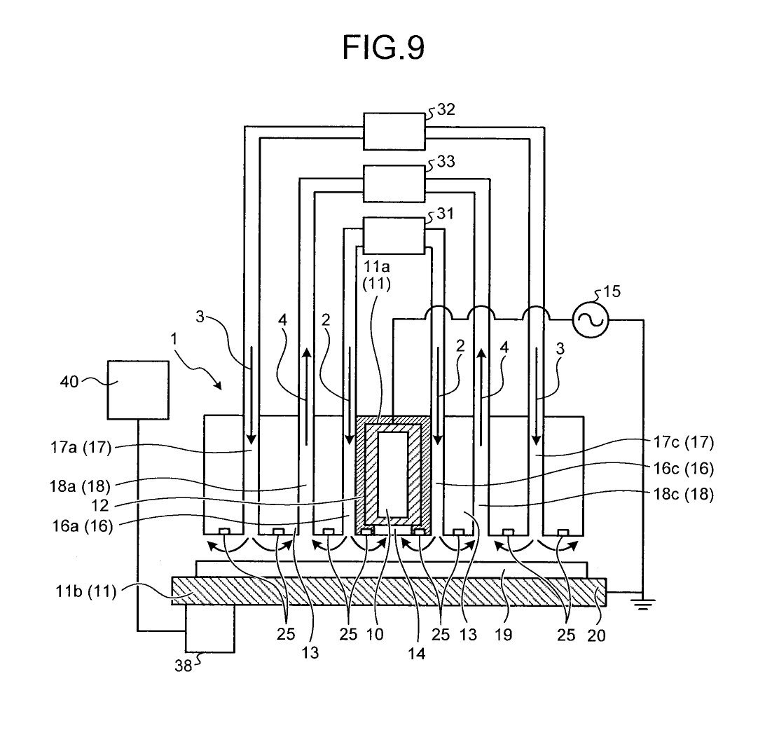

FIG. 9 is a sectional view of a schematic configuration of an atmospheric pressure plasma treatment apparatus according to a fifth embodiment of the present invention. Components same as the components in the embodiments explained above are denoted by the same reference numerals and signs and detailed explanation of the components is omitted. The fifth embodiment is characterized in that an airflow sensor (a flow velocity measuring sensor) 25 for measuring flow velocities is attached to the atmospheric pressure plasma treatment head 1.

Because the airflow sensor 25 is provided, it is possible to directly measure flow velocities between the substrate 19 and the atmospheric pressure plasma treatment head 1. Therefore, it is possible to perform adjustment of a reaction gas amount, a curtain gas amount, and an exhaust amount upstream and downstream. Consequently, it is possible to satisfy, with a smaller flow rate, a condition that an unreacted gas and the like does not flow out to the outside atmosphere and the outside atmosphere does not flow into a plasma generation region (the directions of the gas streams shown in FIG. 3). Flow velocities are measured and not only gas flow rates but also the space between the substrate 19 and the atmospheric pressure plasma treatment head 1 is subjected to feedback control. Consequently, it is possible to perform stable treatment even when the velocity of the stage is increased.

### Sixth Embodiment

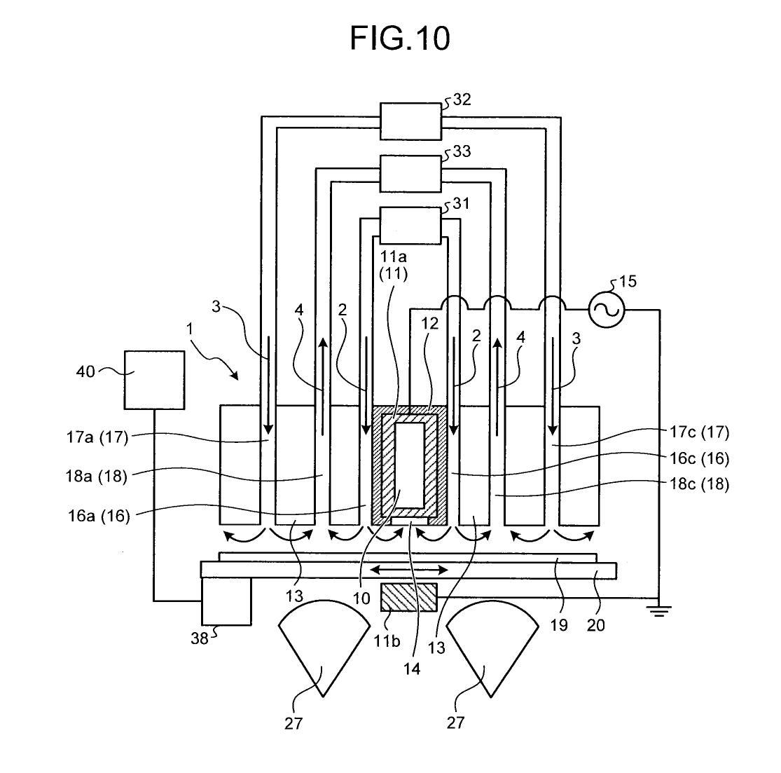

FIG. 10 is a sectional view of a schematic configuration of an atmospheric pressure plasma treatment apparatus according to a sixth embodiment of the present invention. Components same as the components in the embodiments explained above are denoted by the same reference numerals and signs and detailed explanation of the components is omitted. In the sixth embodiment, the ground-side high-frequency electrode 11b is provided separately from the stage 20. The size of the ground-side high-frequency electrode 11b is set to a size substantially the same as the size of the input-side high-frequency electrode 11a. When heating of the substrate 19 is necessary, the stage 20 is heated by a non-contact heating mechanism 27.

With this configuration, only the vicinity of a plasma discharge area can be heated by the non-contact heating mechanism 27. Therefore, it is possible to heat only a necessary place and attain improvement of energy efficiency.

Because the sizes of the input-side high-frequency electrode 11a and the ground-side high-frequency electrode 11b are substantially the same, it is possible to increase plasma density. Therefore there is an effect that the energy efficiency is improved. Further, because the stage 20 is located between the high-frequency electrodes 11, most nonmetal materials including dielectrics such as quartz and ceramic can be used.

However, when it is necessary to heat the stage 20 in a non-contact manner, the stage 20 needs to have low transmittance for an infrared ray. When quartz or the like having high transmittance for infrared ray is used, it is necessary to perform coating of the surface of the stage 20 to increase infrared ray absorptance. Further, in the example explained above, the stage 20 is used. However, if a substrate (a member to be treated) can be directly moved by the moving unit 38, the stage 20 does not have to be provided.

When the size of the solid source (the target or the electrode) 14 is large and a rise of a substrate temperature is insufficient, it is also possible to adopt a configuration in which the ground-side high-frequency electrode 11b is formed in a mesh shape and even the inside of the electrode can be heated in a non-contact manner. With this configuration, if only a necessary place can be heated, there is an effect that the energy efficiency is improved.

### Seventh Embodiment

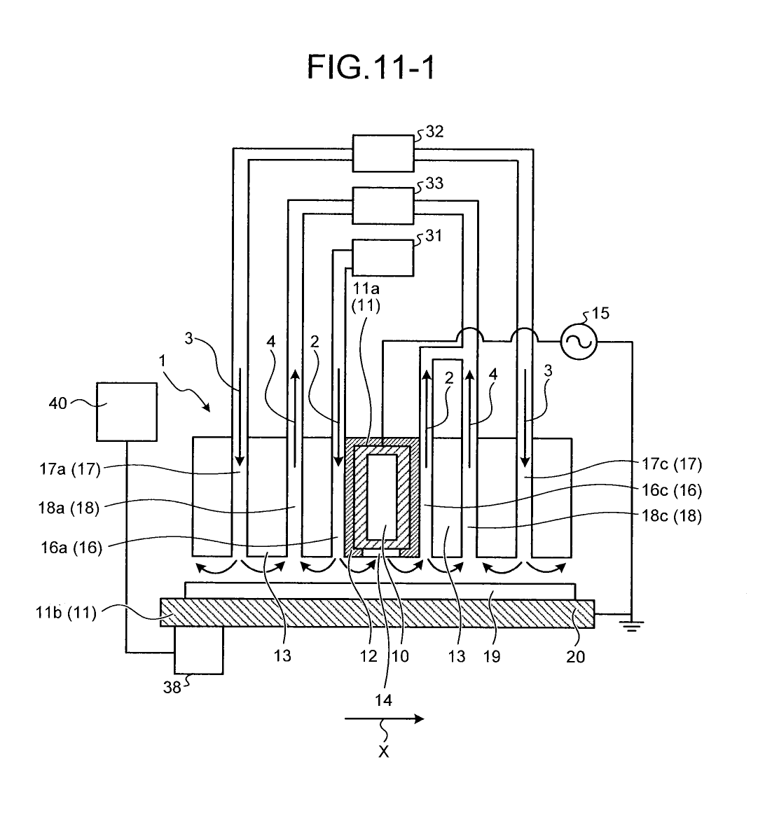

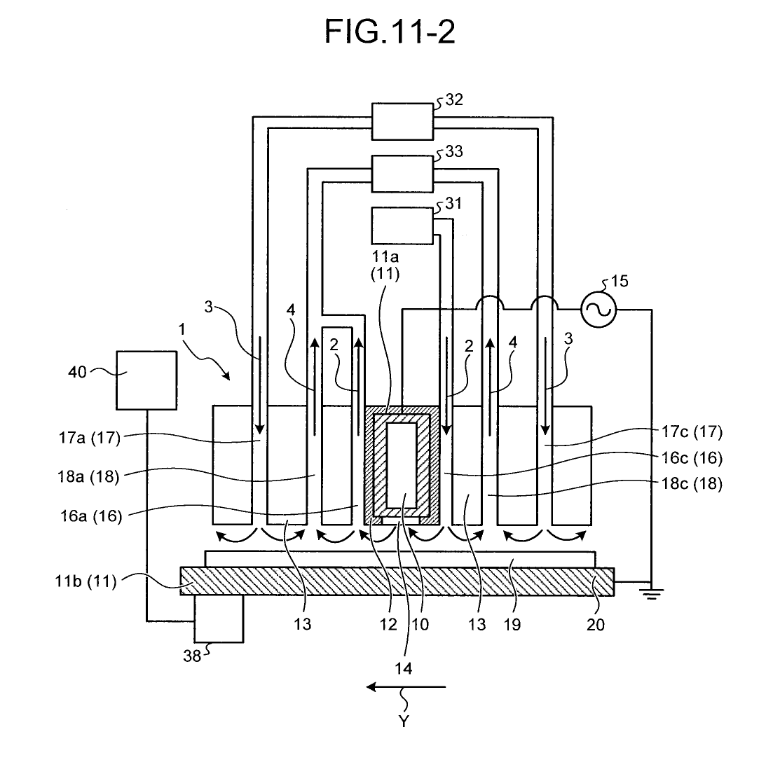

FIG. 11-1 is a sectional view of a schematic configuration of an atmospheric pressure plasma treatment apparatus according to a seventh embodiment of the present invention and is a diagram of a state in which a stage is moving in a direction indicated by the arrow X. Components same as the components in the embodiments explained above are denoted by the same reference numerals and signs and detailed explanation of the components is omitted.

In the seventh embodiment, a part of a reaction gas channel is connected to the exhaust fan 33 to prevent stagnation of gases from occurring between the high-frequency electrodes 11. In FIG. 11-1, the stage 20 moves in the direction indicated by the arrow X. The reaction gas channel 16c located on a downstream side with respect to the moving direction of the stage 20 is connected to the exhaust fan 33.

In the reaction gas channel 16a, gases flow toward the substrate 19 side. In the reaction gas channel 16c, exhaust is performed from the space between the substrate 19 and the atmospheric pressure plasma treatment head 1. Consequently, flows of the gases from the reaction gas channel 16a to the reaction gas channel 16c are generated in the space between the substrate 19 and the atmospheric pressure plasma treatment head 1. Therefore, stagnation of the gasses less easily occurs between the high-frequency electrodes 11.

As shown in FIG. 11-2, when the stage 20 moves in a direction indicated by an arrow Y, the reaction gas channel 16a located on the downstream side with respect to the moving direction of the stage 20 only has to be connected to the exhaust fan 33.

In the reaction gas channel 16c, the gases flow toward the substrate 19 side. In the reaction gas channel 16a, exhaust is performed from the space between the substrate 19 and the atmospheric pressure plasma treatment head 1. Consequently, flows of the gages from the reaction gas channel 16c to the reaction gas channel 16a are generated in the space between the substrate 19 and the atmospheric pressure plasma treatment head 1. Therefore, stagnation of the gases less easily occurs between the high-frequency electrodes 11.

Even in a state in which the stage 20 remains stationary, as shown in FIGS. 11-1 and 11-2, if a part of the reaction gas channel is connected to the exhaust fan 33, the flows of the gases move in one direction between the high-frequency electrodes 11. Therefore, it is possible to suppress stagnation from occurring.

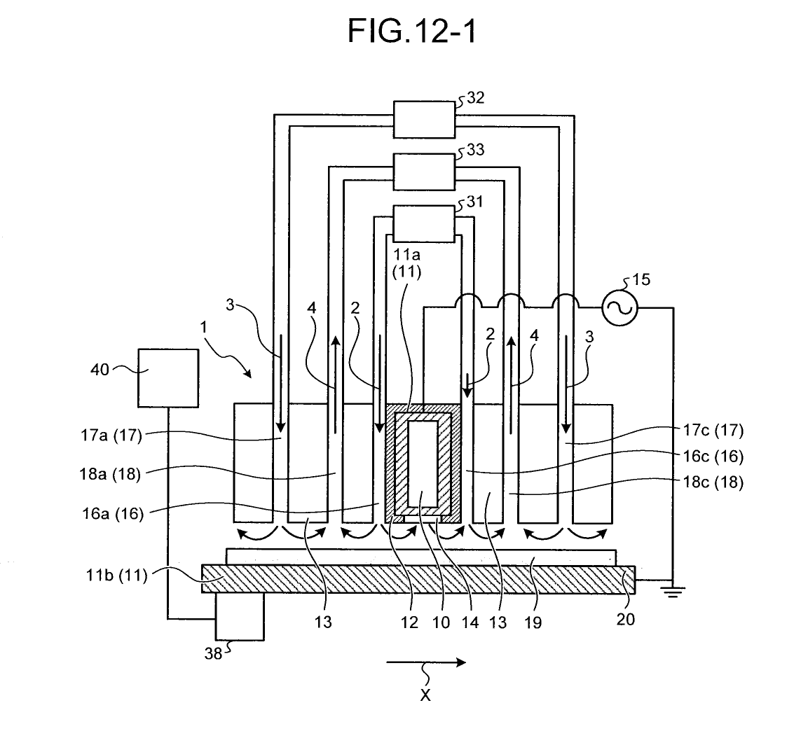

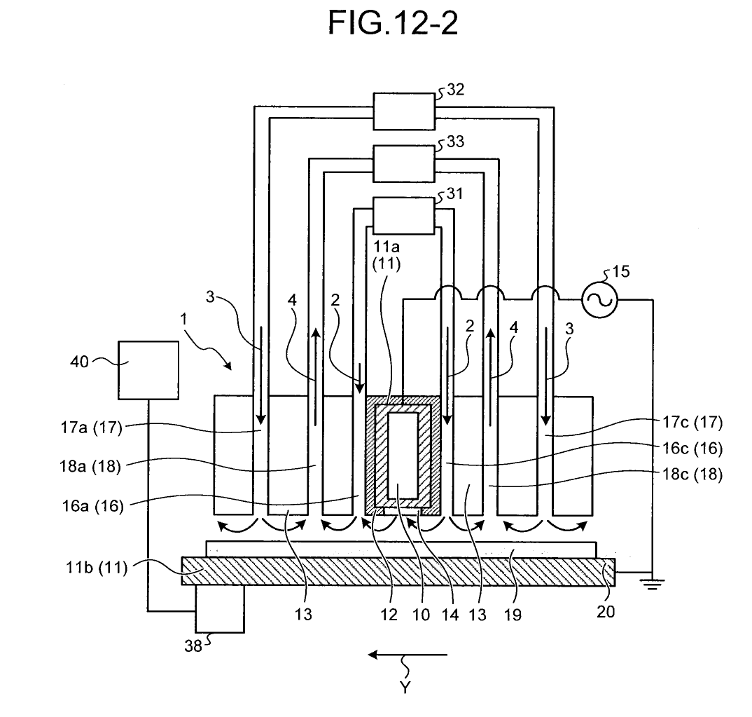

FIG. 12-1 is a sectional view of a schematic configuration of an atmospheric pressure plasma treatment apparatus according to a first modification of the seventh embodiment and is a diagram of a state in which a stage is moving in a direction indicated by the arrow X. In the first modification, a reaction gas flow rate is adjusted among the reaction gas channels 16 (16a to 16d) to prevent stagnation of gases from occurring between the high-frequency electrode 11.

In FIG. 12-1, the stage 20 moves in the direction indicated by the arrow X. The reaction gas flow rate in the reaction gas channel 16c located on the downstream side with respect to the moving direction of the stage 20 is set smaller than a reaction gas flow rate in the reaction gas channel 16a located upstream. Consequently, the flows of the gases between the high-frequency electrodes 11 easily move in one direction. Therefore, it is possible to suppress stagnation from occurring.

When the stage 20 moves in a direction indicated by the arrow Y as shown in FIG. 12-2, the reaction gas flow rate in the reaction gas channel 16a located on the downstream side with respect to the moving direction of the stage 20 is set smaller than the reaction gas flow rate in the reaction gas channel 16c located upstream. Consequently, the flows of the gases easily move in one direction between the high-frequency electrodes 11. Therefore, it is possible to suppress stagnation from occurring.

Even in a state in which the stage 20 remains stationary, if the reaction gas flow rate is adjusted as shown in FIGS. 12-1 and 12-2, the flows of the gases easily move in one direction between the high-frequency electrodes 11. Therefore, it is possible to suppress stagnation from occurring.

### INDUSTRIAL APPLICABILITY

As explained above, the atmospheric pressure plasma treatment apparatus according to the present invention is useful for film formation on a substrate and, in particular, suitable for film formation on the substrate performed by moving a stage.

### REFERENCE SIGNS LIST

1 Atmospheric pressure plasma treatment head

2, 3, 4 Arrows

10 Cooling mechanism

11 High-frequency electrode

11a Input-side high-frequency electrode (first electrode)

11b Ground-side high-frequency electrode (second electrode)

12 Insulator

13 Chanel forming member

14 Solid source (target or electrode)

15 Power supply

16, 16a, 16b, 16c, 16d Reaction gas channels

17, 17a, 17b, 17c, 17d Curtain-gas supply channels

18, 18a, 18b, 18c, 18d Exhaust channels

19 Substrate (member to be treated)

20 Stage

21, 21a, 21c First gas streams

22, 22a, 22c Second gas streams

23, 23a, 23c Third gas streams

25 Airflow sensor (flow velocity measuring sensor)

26, 26a, 26c Fourth gas streams

27 Heating mechanism

30 Protrusion

31 Reaction-gas supply unit (gas supply unit)

32 Curtain-gas supply unit (gas supply unit)

33 Exhaust fan (exhaust unit)

38 Moving unit

40 Control unit

X, Y Arrows

1. An atmospheric pressure plasma treatment apparatus comprising:
an atmospheric pressure plasma treatment head including a first electrode to which an alternating-current power is applied, a grounded second electrode, a reaction gas channel formed in an outer periphery of the first electrode, a reaction gas supplied to a surface to be treated of a member to be treated passing through the reaction gas channel, an exhaust channel formed in an outer periphery of the reaction gas channel, and a curtain-gas supply channel formed in an outer periphery of the exhaust channel;
a moving unit configured to hold the member to be treated to be opposed to the atmospheric pressure plasma treatment head such that the surface to be treated is exposed to the reaction gas supplied from the reaction gas channel and relatively move the atmospheric pressure plasma treatment head and the member to be treated;
a gas supply unit configured to cause the reaction gas to pass through the reaction gas channel and cause the curtain gas to pass through the curtain-gas supply channel;
an exhaust unit configured to exhaust the gasses present between the atmospheric pressure plasma treatment head and the surface to be treated from the exhaust channel; and
a control unit configured to control the gas supply unit and the exhaust unit, wherein
the control unit controls, in an atmosphere in a state in which an electric field is generated between the first electrode and the second electrode by the application of the alternating-current power, a flow rate of the gases exhausted from the exhaust channel to be larger than a flow rate of the reaction gas supplied from the reaction gas channel and controls a flow rate of the curtain gas supplied from the curtain-gas supply channel to be larger than a flow rate of the gases exhausted from the exhaust channel and, when the atmospheric pressure plasma treatment head and the member to be processed are relatively moved by the moving unit, increases a flow rate of the reaction gas and a flow rate of the curtain gas from an opposite direction side of a relative moving direction of the member to be treated with respect to the atmospheric pressure plasma treatment head and reduces a flow rate of the reaction gas and a flow rate of the curtain gas in the relative moving direction side of the member to be processed compared with the flow rates of the reaction gas and the curtain gas flowing when the atmospheric pressure plasma treatment head and the member to be treated are not relatively moved, and controls an exhaust flow rate such that a gas stream between the member to be treated and the atmospheric pressure plasma treatment head flows to an outside of the atmospheric pressure plasma treatment head in an outer peripheral section of the curtain-gas supply channel and flows to the exhaust channel in a collecting section of the exhaust channel.

2. The atmospheric pressure plasma treatment apparatus according to claim 1, wherein a silicon target is arranged in the first electrode.

3. The atmospheric pressure plasma treatment apparatus according to claim 1, wherein the first electrode is provided in a position further apart from the member to be treated than an outlet of the exhaust channel and an outlet of the curtain-gas supply channel.

4. The atmospheric pressure plasma treatment apparatus according to claim 1, wherein a protrusion is provided in a section between the reaction gas channel and the exhaust channel.

5. The atmospheric pressure plasma treatment apparatus according to claim 1, wherein a protrusion is provided in a position opposed to the member to be treated in an outer peripheral section of the atmospheric pressure plasma treatment head.

6. The atmospheric pressure plasma treatment apparatus according to claim 1, wherein a flow velocity measuring sensor is provided between the atmospheric pressure plasma treatment head and the member to be treated.

7. The atmospheric pressure plasma treatment apparatus according to claim 1, further comprising a heating unit configured to heat the member to be treated in a vicinity of a plasma discharge area between the atmospheric pressure plasma treatment head and the member to be treated.

8. The atmospheric pressure plasma treatment apparatus according to claim 7, wherein the heating unit is a non-contact heating device.

9. The atmospheric pressure plasma treatment apparatus according to claim 1, wherein the moving unit includes a stage formed of a dielectric and configured to hold the member to be treated.

10. An atmospheric pressure plasma treatment method for treating a member to be treated using an atmospheric pressure plasma treatment head including a first electrode to which an alternating-current power is applied, a grounded second electrode, a reaction gas channel formed in an outer periphery of the first electrode, a reaction gas supplied to a surface to be treated of the member to be treated passing through the reaction gas channel, an exhaust channel formed in an outer periphery of the reaction gas channel, and a curtain-gas supply channel formed in an outer periphery of the exhaust channel,
the atmospheric pressure plasma treatment method comprising:
applying an alternating-current voltage to the first electrode to generate an electric field between the first electrode and the second electrode in an atmosphere;
causing the reaction gas to pass through the reaction gas channel, causing the curtain gas to pass through the curtain-gas supply channel, and exhausting the gasses present between the atmospheric pressure plasma treatment head and the surface to be treated from the exhaust channel; and
opposing the member to be treated to the atmospheric pressure plasma treatment head such that the surface to be treated is exposed to the reaction gas supplied from the reaction gas channel and relatively moving the atmospheric pressure plasma treatment head and the member to be treated, wherein
a flow rate of the gases exhausted from the exhaust channel is set larger than a flow rate of the reaction gas supplied from the reaction gas channel and a flow rate of the curtain gas supplied from the curtain-gas supply channel is set larger than a flow rate of the gases exhausted from the exhaust channel, and
in the relatively moving the atmospheric pressure plasma treatment head and the member to be treated, a flow rate of the reaction gas and a flow rate of the curtain gas from an opposite direction side of a relative moving direction of the member to be treated with respect to the atmospheric pressure plasma treatment head are increased and a flow rate of the reaction gas and a flow rate of the curtain gas in the relative moving direction side of the member to be processed are reduced compared with the flow rates of the reaction gas and the curtain gas flowing when the atmospheric pressure plasma treatment head and the member to be treated are not relatively moved, and an exhaust flow rate is controlled such that a gas stream between the member to be treated and the atmospheric pressure plasma treatment head flows to an outside of the atmospheric pressure plasma treatment head in an outer peripheral section of the curtain-gas supply channel and flows to the exhaust channel in a collecting section of the exhaust channel.
